(19) United States
(12) Patent Application Publication
(10) Pub. No.: US 2025/0225308 A1
(43) Pub. Date: Jul. 10, 2025

(54) PREDICTING COMPUTE JOB RESOURCES AND COMPUTE TIME FOR COMPUTATION JOBS OF DESIGN OF SEMICONDUCTOR DEVICES USING MACHINE LEARNING MODELS

(71) Applicant: Microchip Technology Incorporated, Chandler, AZ (US)

(72) Inventors: Claudia Anca DUMITRESCU, Bucuresti (RO); Ravi Kumar KODELA, Dublin (IE); Peter RUDDY, Casa Grande, AZ (US); Mandar DESHPANDE, Cupertino, CA (US); Troy HARRISON, Gilbert, AZ (US); Karthik RAJAN, Tempe, AZ (US)

(21) Appl. No.: 19/010,004

(22) Filed: Jan. 4, 2025

Related U.S. Application Data
(60) Provisional application No. 63/618,904, filed on Jan. 9, 2024.

(51) Int. Cl. G06F 30/398; G06F 30/392

(52) U.S. Cl. CPC G06F 30/398; G06F 30/392

(57) ABSTRACT

A job manager may receive a request for a design of a semiconductor device to be verified by a set of computing devices, wherein the request comprises design parameters regarding the design of the semiconductor device. The job manager may provide the design parameters as inputs to a machine learning model trained to predict amounts of computational resources and amounts of compute time for verifying designs of semiconductor devices. The job manager may obtain, as an output from the machine learning model, a predicted amount of computational resources and a predicted amount of compute time for verifying the design of the semiconductor device. The job manager may determine an availability of resources, of the set of computing devices, for verifying the design of the semiconductor device. The job manager may cause the design of the semiconductor device to be verified by one or more computing devices.

### CROSS-REFERENCE TO RELATED APPLICATION

This patent application claims priority to Provisional Patent Application No. 63/618,904, filed on Jan. 9, 2024, and entitled “PREDICTING COMPUTE JOB RESOURCES AND RUNTIME FOR COMPUTATION JOBS OF DESIGN OF SEMICONDUCTOR DEVICES USING MACHINE LEARNING MODELS.” The disclosure of the prior application is considered part of and is incorporated by reference into this patent application.

### FIELD

The present disclosure generally relates to electronic design automation (EDA) for semiconductor devices and, for example, to the use a machine learning model to predict computational hardware and software resources to be used and an amount of time to be spent for design verification of semiconductor devices.

### BACKGROUND

A server farm (or computer farm) is a cluster of computing devices (e.g., computer servers) setup to perform different computational tasks submitted by different users. The different computational tasks utilize different amounts of computational hardware resources and/or are completed in different amounts of time. For example, a first task may utilize approximately 10 MB of random access memory (RAM). Alternatively, a second task may utilize approximately 100 GB of RAM. Additionally, or alternatively, the first computational task may be completed within minutes while the second computational task may be completed in one or more hours.

### SUMMARY

In some implementations, a method comprising: receiving a request for a design of a semiconductor device to be verified by a set of computing devices, wherein the request comprises design parameters regarding the design of the semiconductor device; providing the design parameters as inputs to a machine learning model trained to predict amounts of computational resources and amounts of compute time for verifying designs of semiconductor devices; obtaining, as an output from the machine learning model, a predicted amount of computational resources and a predicted amount of compute time for verifying the design of the semiconductor device; determining an availability of resources, of the set of computing devices, for verifying the design of the semiconductor device; and causing the design of the semiconductor device to be verified by one or more computing devices, of the set of computing devices, based on the availability of resources and the predicted amount of computational resources.

In some implementations, a system comprising: one or more processing units adapted to: receive a request for a design of a semiconductor device to be verified by a set of computing devices, wherein the request comprises design parameters regarding the design of the semiconductor device; provide the design parameters as inputs to a machine learning model trained to predict amounts of computational resources and amounts of compute time for verifying designs of semiconductor devices; obtain, as an output from the machine learning model, a predicted amount of computational resources and a predicted amount of compute time for verifying the design of the semiconductor device; determine, based on the predicted amount of computational resources and the predicted amount of compute time, a quantity of cores to be used for verifying the design of the semiconductor device and a quantity of licenses to be used for verifying the design of the semiconductor device; and cause the design of the semiconductor device to be verified by one or more computing devices, of the set of computing devices, based on the quantity of cores, the quantity of licenses, and the amount of computational resources.

In some implementations, a computer program product comprising: one or more computer readable storage media, and program instructions collectively stored on the one or more computer readable storage media, the program instructions comprising: program instructions to receive a request for a design of a semiconductor device to be verified by a set of computing devices, wherein the request comprises design parameters regarding the design of the semiconductor device; program instructions to provide the design parameters as inputs to a machine learning model trained to predict amounts of computational resources and amounts of compute time for verifying designs of semiconductor devices; program instructions to obtain, as an output from the machine learning model, a predicted amount of computational resources and a predicted amount of compute time for verifying the design of the semiconductor device; program instructions to determine, based on the predicted amount of computational resources and the predicted amount of compute time, a quantity of cores to be used for verifying the design of the semiconductor device and a quantity of licenses to be used for verifying the design of the semiconductor device; and program instructions to cause the design of the semiconductor device to be verified by one or more computing devices, of the set of computing devices, based on the quantity of cores, the quantity of licenses, and the amount of computational resources.

### BRIEF DESCRIPTION OF THE DRAWINGS

FIG. 1 is a block diagram illustrating an example of an electronic design automation (EDA) environment, in accordance with the present disclosure.

FIG. 2 is a block diagram illustrating an example of a device, in accordance with the present disclosure.

FIG. 3 is a schematic block diagram illustrating an example process for using a machine learning component to predict computation resources to be used and time for an EDA operation, in accordance with the present disclosure.

FIG. 4 is a schematic block diagram illustrating another example process for using a machine learning component to predict computation resources to be used and time for an EDA operation, in accordance with the present disclosure.

FIG. 5 is a flow diagram illustrating a method for using a machine learning model to predict computational hardware and software resources to be used and an amount of time to be spent for design verification of semiconductor devices, in accordance with the present disclosure.

### DETAILED DESCRIPTION

The following detailed description of example implementations refers to the accompanying drawings. The same reference numbers in different drawings may identify the same or similar elements.

Semiconductor design is a complex and multifaceted field that encompasses the creation, development, and optimization of integrated circuits (ICs) and other semiconductor devices. This process involves multiple stages, including conceptualization, simulation, implementation, and verification, each requiring specialized knowledge, tools, and computational resources. The design of modern semiconductors often involves billions of transistors and intricate interconnections, necessitating advanced techniques and powerful computational resources to manage the complexity.

Simulation, implementation, and physical verification are examples of tasks in semiconductor design. Simulation allows designers to model and predict the behavior of circuits before physical fabrication, helping to identify and resolve potential issues early in the design process. Implementation involves translating the high-level design into a physical layout that can be manufactured, considering factors such as power consumption, timing, and area constraints. Physical verification ensures that the implemented design meets all specified requirements and functions correctly under various design rules, constraints, and conditions.

These design tasks rely heavily on computational resources and specialized software tools. Central Processing Units (CPUs) and CPU cores provide the processing power for running complex algorithms and simulations. Random Access Memory (RAM) is used for handling large datasets and enabling quick access to design information. Electronic Design Automation (EDA) software tools, which often require specific licenses, are used throughout the design process for tasks such as schematic capture, logic synthesis, place and route, and design rule checking. The efficient allocation and utilization of these resources are critical for managing the time and cost associated with semiconductor design projects.

EDA software tools can be implemented in server farms. A server farm (or computer farm) may be used to perform different computational tasks (or jobs) submitted by different users. As an example, the computational tasks may include tasks relating to designs, generation of designs, simulation and functional verification of designs, and physical verification of designs of semiconductor devices. In some situations, computing devices of the server farm may be managed by job resource management tools (or “tools”). For example, the tools may queue, schedule, and control multiple jobs on the server farm and allocate computational resources for the jobs. The tools may be implemented using a combination of hardware and software.

Currently, the tools do not determine the types of computational resources to be used to perform the jobs, do not determine an amount of computational resources to be used to perform jobs, do not estimate the amount of time to complete the jobs, and do not determine a number of licenses to be used to perform the jobs. Additionally, users submitting requests for the jobs provide default information that does not specifically or accurately identify the amount of computational resources and the number of licenses to be used to perform the jobs.

Accordingly, the tools do not allocate the appropriate amount of computational resources and the appropriate number of licenses to be used to perform the jobs. Therefore, the tools may cause the computing devices and license servers (of the server farmer) to be utilized inefficiently. Moreover, the tools may cause the job to be completed over longer periods of time. Excessive resources allocation when not needed may cause other jobs to wait in queue for longer due to unavailability of resources for the other jobs. In this regard, the tools may cause loss of productivity at the server farm and slow down the semiconductor design processes for multiple users, tasks and designs.

Implementations described herein are directed to leveraging machine learning (ML) components to predict compute job resources and run time. An ML component refers to software capable of performing machine learning. ML is a subset of artificial intelligence (AI) that involves the development of algorithms and statistical models enabling computers to perform tasks without explicit programming. ML leverages large datasets to identify patterns, make decisions, and improve over time based on experience. ML focuses on creating systems that can learn from data, adapt to new inputs, and generate predictions or actions.

For example, an ML component may be or include one or more ML models, ML algorithms, and/or ML systems including combinations of ML algorithms and ML models. An ML component may be implemented on any number of different hardware devices and may include one or more machine learning models. ML is a field of study that gives computers the ability to perform certain tasks without being explicitly programmed to perform those tasks. In traditional computing, a programmer would encode instructions (e.g., to solve a quadratic equation using the quadratic formula), and the computer would perform those exact instructions. In contrast, in ML, a computer can be provided with examples and be trained to perform a task such as prediction or classification, without the programmer encoding explicit instructions for the task. ML explores the study and construction of algorithms, also referred to herein as tools, models, and/or components, which may learn from existing data and make predictions about new data. Such ML tools operate by building a model from example training data in order to make data-driven predictions or decisions expressed as outputs or assessments. Although example embodiments are presented with respect to a few ML models, the principles presented herein may be applied to other ML models. In some example embodiments, different ML models may be used. ML models may include, for example, K-means clustering models, linear regression models, Logistic Regression (LR) models, Naive-Bayes models, Random Forest (RF) regression models, gradient boost models, neural networks (NN), matrix factorization models, and/or Support Vector Machines (SVMs).

Two common types of problems in ML are classification problems and regression problems. Classification problems, also referred to as categorization problems, aim at classifying items into one of several category values (for example, is this object an apple or an orange). Regression algorithms aim at quantifying some items (for example, by providing a value that is a real number). The ML components utilize the training data to find correlations among identified features that affect the outcome. The ML components utilize features for analyzing the data to generate assessments. A feature is an individual measurable property of a phenomenon being observed. The concept of a feature is related to that of an explanatory variable used in statistical techniques such as linear regression. Choosing informative, discriminating, and independent features is important for effective operation of the ML in pattern recognition, classification, and regression. Features may be of different types, such as numeric features, strings, and graphs.

ML components utilize the training data to find correlations among the identified features that affect the outcome or assessment. In some example embodiments, the training data includes labeled data, which is known data for one or more identified features and one or more outcomes. With the training data and the identified features, the ML component may be trained. The ML component appraises the value of the features as they correlate to the training data. The result of the training is the trained ML component. When the ML component is used to perform an assessment, new data is provided as an input to the trained ML component, and the ML component generates an assessment as output.

ML techniques train models to accurately make predictions on data fed into the models (e.g., what was said by a user in a given utterance; whether a noun is a person, place, or thing; what the weather will be like tomorrow). During a learning phase, the models are developed against a training dataset of inputs to optimize the models to correctly predict the output for a given input. Generally, the learning phase may be supervised, semi-supervised, or unsupervised; indicating a decreasing level to which the “correct” outputs are provided in correspondence to the training inputs. In a supervised learning phase, all of the outputs are provided to the model and the model is directed to develop a general rule or algorithm that maps the input to the output. In contrast, in an unsupervised learning phase, the desired output is not provided for the inputs so that the model may develop its own rules to discover relationships within the training dataset. In a semi-supervised learning phase, an incompletely labeled training set is provided, with some of the outputs known and some unknown for the training dataset.

Models may be run against a training dataset for several epochs (e.g., iterations), in which the training dataset is repeatedly fed into the model to refine its results. For example, in a supervised learning phase, a model is developed to predict the output for a given set of inputs, and is evaluated over several epochs to more reliably provide the output that is specified as corresponding to the given input for the greatest number of inputs for the training dataset. In another example, for an unsupervised learning phase, a model is developed to cluster the dataset into n groups, and is evaluated over several epochs as to how consistently it places a given input into a given group and how reliably it produces the n desired clusters across each epoch.

Once an epoch is run, the models are evaluated and the values of their variables are adjusted to attempt to better refine the model in an iterative fashion. In various aspects, the evaluations are biased against false negatives, biased against false positives, or evenly biased with respect to the overall accuracy of the model. The values may be adjusted in several ways depending on the ML technique used. For example, in a genetic or evolutionary algorithm, the values for the models that are most successful in predicting the desired outputs are used to develop values for models to use during the subsequent epoch, which may include random variation/mutation to provide additional data points.

Each model develops a rule or algorithm over several epochs by varying the values of one or more variables affecting the inputs to more closely map to a desired result, but as the training dataset may be varied, and is preferably very large, perfect accuracy and precision may not be achievable. A number of epochs that make up a learning phase, therefore, may be set as a given number of trials or a fixed time/computing budget, or may be terminated before that number/budget is reached when the accuracy of a given model is high enough or low enough or an accuracy plateau has been reached. For example, if the training phase is designed to run n epochs and produce a model with at least 95% accuracy, and such a model is produced before the nth epoch, the learning phase may end early and use the produced model satisfying the end-goal accuracy threshold. Similarly, if a given model is inaccurate enough to satisfy a random chance threshold (e.g., the model is only 55% accurate in determining true/false outputs for given inputs), the learning phase for that model may be terminated early, although other models in the learning phase may continue training. Similarly, when a given model continues to provide similar accuracy or vacillate in its results across multiple epochs—having reached a performance plateau—the learning phase for the given model may terminate before the epoch number/computing budget is reached.

Once the learning phase is complete, the models are finalized. In some example embodiments, models that are finalized are evaluated against testing criteria. In a first example, a testing dataset that includes known outputs for its inputs is fed into the finalized models to determine an accuracy of the model in handling data that it has not been trained on. In a second example, a false positive rate or false negative rate may be used to evaluate the models after finalization. In a third example, a delineation between data clustering is used to select a model that produces the clearest bounds for its clusters of data.

Machine learning models may be implemented for use in a variety of use cases (e.g., language processing, image feature extraction, cyberthreat detection, or recommendation production), using a variety of approaches (e.g., supervised learning, unsupervised learning, or reinforcement learning), and in a variety of structures (e.g., a neural network, decision tree, linear regression, vector machine, Bayesian network, genetic algorithm, or deep learning system).

In some cases, the AI training software may employ reinforcement learning (RL), which is a method of training neural networks. Similar to human learning, RL trains neural networks through trial and error. Specifically, the neural network produces an output, receives feedback regarding this output, and then learns from the feedback. Problems addressed via RL are typically structured in a consistent format. Specifically, an agent interacts with an environment, maintaining a state within this environment and producing actions that can alter the current state. As the agent interacts with the environment, it can receive both positive and negative rewards for its actions. The agent's objective is to maximize the rewards received, although not every action is associated with a reward. Rewards may have a long horizon, necessitating several correct, consecutive actions to generate any positive reward. In mathematical terms, RL may be described as a Markov decision process (MDP). An MDP includes states, actions, rewards, transitions, and a policy. States and actions have discrete values, while rewards are real numbers. In an MDP, a policy (referred to herein, interchangeably as a “policy model”) takes a state as input and outputs a probability distribution over possible actions. Given this output, a decision can be made for the action to be taken from a current state, and the transition is then a function that outputs the next state based upon the prior state and chosen action. Using these components, the agent can interact with the environment in an iterative fashion to generate a trained policy.

Reinforcement learning proves to be an advantageous and promising learning algorithm for neural networks because it allows learning from non-differentiable signals, which are incompatible with supervised learning. This capability enables the AI training software to learn from arbitrary feedback on a neural network's output.

Implementations described herein are directed to using a machine learning model to predict computational hardware resources (e.g., an amount of RAM and a number of CPU cores) to be used for physical design verification of semiconductor devices and predict an amount of time (e.g., CPU time and run time) to be spent for the design verification. The CPU time is the sum of compute time across all CPU cores used for the compute job (e.g., the total amount of time used by the CPU cores). Run time is the time from start to finish of the compute job. The machine learning model may be trained using training data that includes parameters obtained from process design kit set up, design rule checking (DRC) rules, layout stream output log file, and DRC run log file.

For example, the training data may include one or more of historical computational resources used for verifying designs of semiconductor devices, historical amounts of CPU time required for verifying the designs, historical data identifying foundries, historical data identify technology nodes of the foundries, and sizes of files depicting a layout of the semiconductor devices. The machine learning model may be trained using deep learning, supervised learning, unsupervised learning, and/or reinforcement learning. As an example, the machine learning model may include a gradient boost model.

Based on the predicted computational hardware resources and amount of CPU time, implementations described herein may determine a number of cores to be used for the design verification, the amount of RAM to be used for the design verification, a number of licenses to be used for the design verification, and a type or an amount of other computational hardware resources to be used for the design verification. Implementations described herein may determine an availability of the cores, the RAM, the licenses, and the other computational hardware resources, at the server farm, for the design verification. Implementations described herein may determine a type of computer operating systems, a machine grouping or queue list, and a graphical processing unit.

Implementations described herein may be used for different tasks relating to EDA for semiconductor devices. Implementations described herein may be used for one or more of layout versus schematic (LVS) checks, spice simulations, and power integrity analysis.

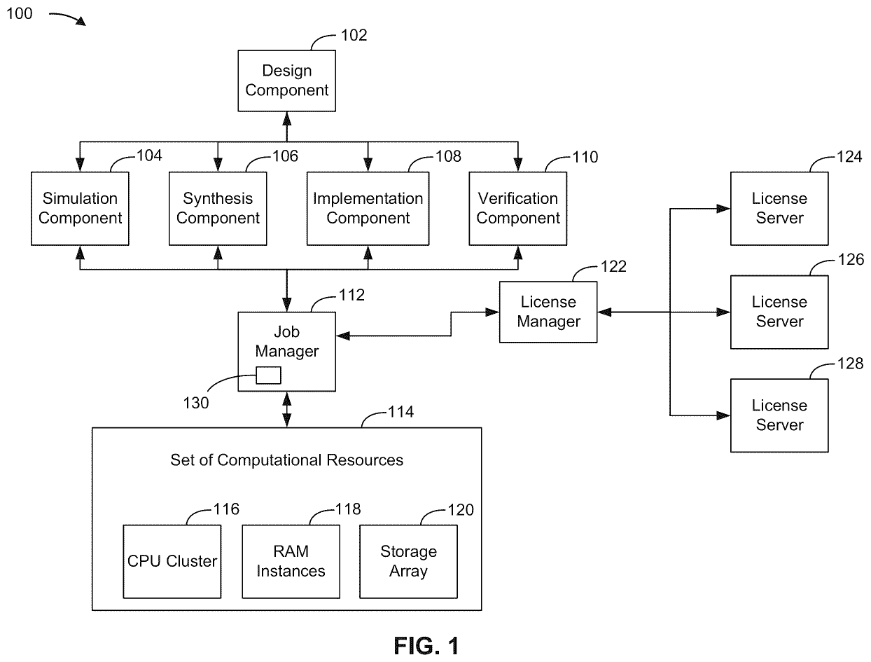

FIG. 1 is a block diagram illustrating an example of an EDA environment 100, in accordance with the present disclosure. As shown, the EDA environment 100 includes a design component 102, a simulation component 104, a synthesis component 106, an implementation component 108, a verification component 110, a job manager 112, and a set 114 of computational resources. The set 114 of computational resources includes a CPU cluster 116, RAM instances 118, and a storage array 120. The EDA environment also includes a license manager 122, license servers 124, 126, and 128, and a resource estimator 130.

The design component 102 may be responsible for creating and modifying the initial design of a semiconductor device. This component may include tools for schematic capture, layout design, and other aspects of the initial design process. The design component 102 may interact with other components of the EDA environment 100 to ensure that the design meets specified requirements and constraints.

The simulation component 104 may be used to model and predict the behavior of the semiconductor device before physical fabrication. This component may employ various simulation techniques, including circuit simulation, timing analysis, and power analysis. The simulation component 104 may help designers identify and resolve potential issues early in the design process, reducing the need for costly redesigns later.

The synthesis component 106 may be responsible for translating the high-level design description into a gate-level netlist. This component may optimize the design for various parameters such as area, power consumption, and timing. The synthesis component 106 may work closely with the implementation component 108 to ensure that the synthesized design can be effectively mapped to the target technology.

The implementation component 108 may handle the physical implementation of the design, including tasks such as placement and routing. This component may work to optimize the physical layout of the semiconductor device while adhering to design rules and constraints. The implementation component 108 may interact with the verification component 110 to ensure that the implemented design meets all specified requirements.

The verification component 110 may be responsible for various types of design verification, including DRC, LVS checks, and litho-friendly design checks. This component may help ensure that the design is manufacturable and functions as intended. The verification component 110 may work iteratively with other components to identify and resolve any issues in the design.

The job manager 112 may oversee the allocation and management of computational resources for various EDA tasks. The job manager 112 may queue, schedule, and control multiple jobs on the set of computational resources 114. The set of computational resources 114 may include various hardware components necessary for EDA tasks. This may include a CPU cluster 116 for processing, RAM instances 118 for temporary data storage and quick access, and a storage array 120 for long-term data storage. These resources may be dynamically allocated to different tasks based on the needs determined by the job manager 112.

The license manager 122 may oversee the allocation and management of software licenses required for various EDA tools. It may interact with multiple license servers (124, 126, 128) to ensure that the necessary licenses are available for each job. The license manager 122 may work in conjunction with the job manager 112 to optimize license usage across multiple jobs and users.

The job manager 112 may include a resource estimator 130. The resource estimator 130 may be used to estimate or predict the set 114 of computational resources to be used to perform the jobs that are submitted by users. The resource estimator 130 may use a machine learning component to estimate or predict the set 114 of computational resources to be used to perform the jobs that are submitted by users. For example, the resource estimator 130 may employ machine learning techniques to predict the computational resources and time required for various EDA tasks. The resource estimator 130 may take into account factors such as design complexity, technology node, and historical data to make these predictions. The resource estimator 130 may provide this information to the job manager 112 to help optimize resource allocation.

The resource estimator 130 may use any number of machine learning models to predict the set 114 of computational resources to be used to perform the jobs that are submitted by users. The machine learning models may be trained using training data that includes parameters obtained from process design kit set up, DRC rules, layout stream output log file, and DRC run log file. For example, the training data may include one or more of historical computational resources used for verifying designs of semiconductor devices, historical amounts of time for verifying the designs, historical data identifying foundries, historical data identify technology nodes of the foundries, and sizes of files depicting a layout of the semiconductor devices. The machine learning model may be trained using deep learning, supervised learning, unsupervised learning, or reinforcement learning.

Based on the predicted set of computational resources, the resource estimator 130 may determine a number of CPU cores to be used for the design verification, the amount of RAM to be used for the design verification, a number of licenses to be used for the design verification, and a type or an amount of other computational hardware resources to be used for the design verification. Implementations described herein may determine an availability of the cores, the RAM, the licenses, and the other computational hardware resources, at the server farm, for the design verification. Implementations described herein may determine a type of computer operating systems, a machine grouping or queue list, and a graphical processing unit.

In some implementations, the job manager 112 may be configured to receive design parameters regarding a design of a semiconductor device, wherein the design parameters are included in a request for a design of a semiconductor device to be verified by a set of computing devices and wherein the design parameters identify a foundry, a technology node of the foundry, and a size of a file depicting a layout of the semiconductor device; provide the design parameters as inputs to a machine learning model trained to predict amounts of computational resources and amounts of time for verifying designs of semiconductor devices, wherein the machine learning model is trained using training data that includes historical design parameters for the designs, historical computational resources used for verifying the designs, and historical amounts of time for verifying the designs; obtain, as an output from the machine learning model, a prediction of an amount of computational resources and an amount of time for verifying the design of the semiconductor device; determine an availability of resources, of the set of computing devices, for verifying the design of the semiconductor device; and cause the design of the semiconductor device to be verified by one or more computing devices, of the set of computing devices, based on the availability of resources and the estimated amount of computational resources.

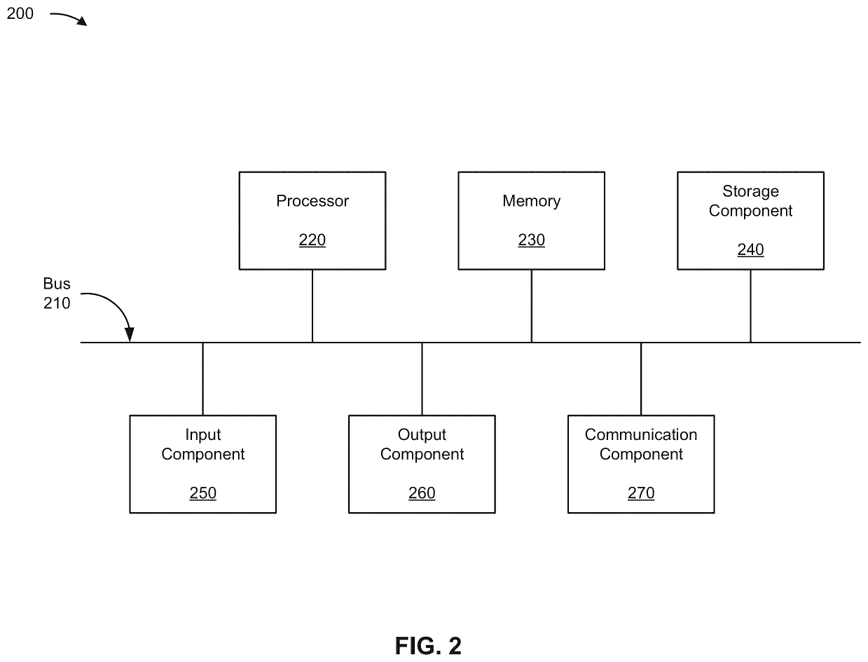

FIG. 2 is a diagram of example components of a device 200, in accordance with the present disclosure. The device 200 may be used to implement one or more components of FIG. 1 such as, for example, the design component 102, the simulation component 104, the synthesis component 106, the implementation component 108, the verification component 110, the job manager 112, the set of computational resources 114, the license manager 122, the license server 124-126, and/or the resource estimator 130. In some implementations, the device 200 may refer to one or more devices 200 and one or more components of device 200. As shown in FIG. 2, device 200 may include a bus 210, a processor 220, a memory 230, a storage component 240, an input component 250, an output component 260, and a communication component 270. Device 200 may be, for example, a computing device.

Bus 210 includes a component that enables wired or wireless communication among the components of device 200. Processor 220 may be a central processing unit, a graphics processing unit, a microprocessor, a controller, a microcontroller, a digital signal processor, a field-programmable gate array, an application-specific integrated circuit, or another type of processing component. Processor 220 is implemented in hardware, firmware, or a combination of hardware and software. In some implementations, processor 220 includes one or more processors capable of being programmed to perform a function. Memory 230 includes a random access memory, a read only memory, or another type of memory (e.g., a flash memory, a magnetic memory, or an optical memory).

Storage component 240 stores information or software related to the operation of device 200. For example, storage component 240 may include a hard disk drive, a magnetic disk drive, an optical disk drive, a solid state disk drive, a compact disc, a digital versatile disc, or another type of non-transitory computer-readable medium. Input component 250 enables device 200 to receive input, such as user input or sensed inputs. For example, input component 250 may include a touch screen, a keyboard, a keypad, a mouse, a button, a microphone, a switch, a sensor, a global positioning system component, an accelerometer, a gyroscope, or an actuator. Output component 260 enables device 200 to provide output, such as via a display, a speaker, or one or more light-emitting diodes. Communication component 270 enables device 200 to communicate with other devices, such as via a wired connection or a wireless connection. For example, communication component 270 may include a receiver, a transmitter, a transceiver, a modem, a network interface card, or an antenna.

Device 200 may perform one or more processes described herein. For example, a non-transitory computer-readable medium (e.g., memory 230 or storage component 240) may store a set of instructions (e.g., one or more instructions, code, software code, or program code) for execution by processor 220. Processor 220 may execute the set of instructions to perform one or more processes described herein. In some implementations, execution of the set of instructions, by one or more processors 220, causes the one or more processors 220 or the device 200 to perform one or more processes described herein. In some cases, a number of processors 220 may perform a process in parallel. In some cases, one or more processors may perform one or more aspects of a process while one or more other processors may perform one or more other aspects of the process. Similarly, instructions may be duplicated, distributed, and/or partitioned across two or more memories 230. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 2 are provided as an example. Device 200 may include additional components, fewer components, different components, or differently arranged components than those shown in FIG. 2. For example, the processor 220 may refer to two or more processors and the memory 230 may refer to two or more memories 230. Additionally, or alternatively, a set of components (e.g., one or more components) of device 200 may perform one or more functions described as being performed by another set of components of device 200.

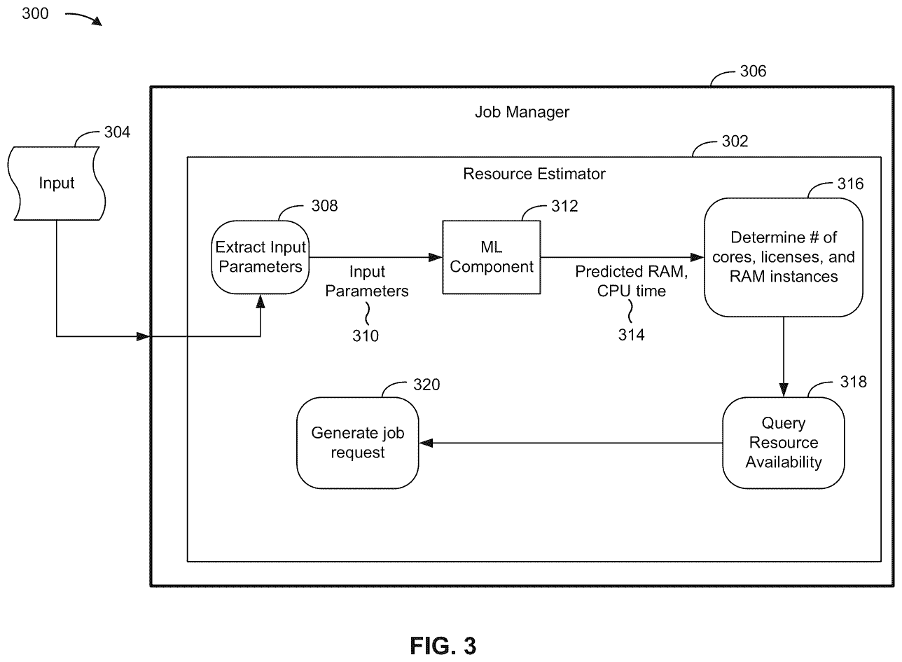

FIG. 3 is a schematic block diagram illustrating an example process for using a machine learning component to predict computation and time resources to be used for an EDA operation, in accordance with the present disclosure. The process 300 may be implemented by various components of an EDA environment such as, for example, the EDA environment 100 shown in FIG. 1. For example, in some implementations, the process 300 may be implemented by a job manager (e.g., the job manager 112 shown in FIG. 1).

The process 300 begins with a job manager 306 receiving an input 304, which may include design parameters regarding a design of a semiconductor device. The job manager 306 may be similar to the job manager 112, described above in connection with FIG. 1. These design parameters may be included in a request for a design of a semiconductor device to be verified by a set of computing devices. In some implementations, the design parameters may identify a foundry, a technology node of the foundry, and a size of a file depicting a layout of the semiconductor device. Additionally, the design parameters may include information about the number of shapes in the semiconductor design and the number of rules to be checked during verification. The job manager 306 may provide the input 304 to a resource estimator 302 (which may be included in the job manager 306). The resource estimator 302 may be similar to resource estimator 130, described above in connection with FIG. 1.

At block 308, the resource estimator 302 processes the input 304 to extract relevant input parameters 310. These input parameters 310 are then provided as inputs to an ML component 312. The ML component 312 may be a trained machine learning model, such as a gradient boosting model, neural network, or other suitable machine learning algorithm. The ML component 312 is trained to predict amounts of computational resources and amounts of time for verifying designs of semiconductor devices.

The ML component 312 may be trained using training data that includes historical design parameters for the designs, historical computational resources used for verifying the designs, and historical amounts of time for verifying the designs. The training data may include historical number of shapes of the designs and historical number of rules checked for the designs. This training data may be derived from various sources, including process design kit setup information, DRC rules, layout stream output log files, and DRC run log files. The training process may employ supervised learning, unsupervised learning, or reinforcement learning techniques, depending on the specific implementation and available data.

Based on the input parameters 310, the ML component 312 generates predictions for the required RAM and CPU time 314 for the verification process. These predictions are not limited to just RAM and CPU time but may also include other computational resources such as the number of CPU cores, the amount of storage required, and the number of software licenses needed.

At block 316, the resource estimator 302 processes the predictions from the ML component 312. This processing may involve determining, based on the predicted amount of computational resources and time, a quantity of cores to be used for verifying the design of the semiconductor device, and a quantity of licenses to be used for the verification process. The resource estimator 302 may also determine other resource requirements, such as the amount of RAM, storage space, and any specialized hardware (e.g., graphics processing units (GPUs)) that may be needed for the verification task.

Based on the processed predictions, the resource estimator 302 may determine an availability of resources for verifying the design of the semiconductor device at block 318. This determination may involve checking the current utilization of CPU cores, RAM, storage, and software licenses across the set of computing devices.

If the required resources are not immediately available, the job manager 306 may implement various strategies to optimize resource allocation. For example, it may adjust the amount of computational resources for verifying the design of the semiconductor device based on the current availability. The job manager 306 may reduce the amount of computational resources until a threshold availability of cores and licenses is met. This adaptive approach ensures efficient utilization of resources while still meeting the verification requirements.

In some implementations, the job manager 306 may also consider factors such as job priority, expected completion time, and overall system load when allocating resources. It may employ sophisticated scheduling algorithms to optimize the use of available resources across multiple concurrent jobs.

At block 320, once the resource availability is determined and any necessary adjustments are made, the resource estimator 302 may a generate job request to verify the design of the semiconductor device. For example, the resource estimator 302 may cause the design of the semiconductor device to be verified by one or more computing devices of the set of computing devices. The verification process is initiated with the calculated computational resources based on the availability of resources and the predicted amount of computational resources.

In some cases, the job manager 306 may continually monitor the resource usage and job progress. If discrepancies are observed between the predicted and actual resource usage or completion time, this information may be fed back to the resource estimator 302 to improve future predictions. This feedback loop allows the ML component 312 to continually learn and adapt, improving its prediction accuracy over time.

The process 300 may also include additional steps not explicitly shown in the figure. For example, after the verification is complete, the results may be analyzed and any issues identified may be reported back to the design component 102 for further refinement of the semiconductor device design. Additionally, the actual resource usage and completion time may be recorded and added to the historical data used for training the ML component 312, further enhancing its predictive capabilities for future jobs.

In alternative implementations, the process 300 may be extended to handle other EDA tasks beyond design verification, such as simulation, synthesis, or physical implementation. The ML component 312 may be trained on a wider range of EDA tasks, allowing it to predict resource requirements for various stages of the semiconductor design process. This comprehensive approach can lead to more efficient resource allocation across the entire EDA workflow.

By leveraging machine learning to predict computational resource requirements and runtime for EDA tasks, the process 300 enables more efficient utilization of computing resources, reduces job queue times, and ultimately accelerates the semiconductor design and verification process. This approach may be particularly valuable in the context of increasingly complex semiconductor designs and the growing computational demands of modern EDA tools.

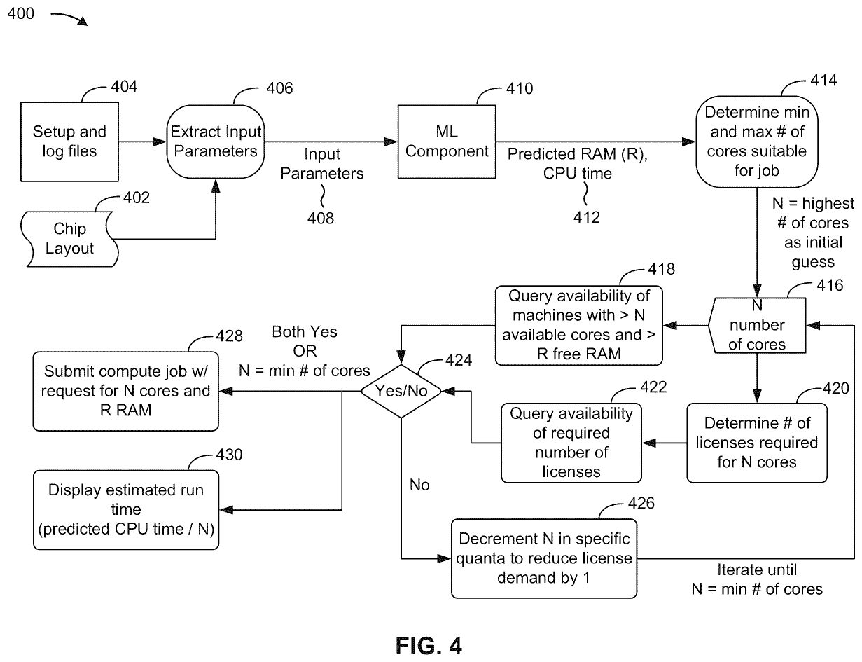

FIG. 4 is a schematic block diagram illustrating another example process 400 for using a machine learning component to predict computation and time resources to be used for an EDA operation, in accordance with the present disclosure. The process 400 begins with two primary inputs: a chip layout 402 and setup and log files 404. The chip layout 402 may include detailed information about the semiconductor device design, such as the number and types of components, their arrangement, interconnections, and overall complexity. This layout information is crucial for accurately estimating the computational resources required for various EDA tasks, particularly for DRC and LVS verification processes. The setup and log files 404 may include historical data and configuration information. These files may include process design kit (PDK) setup details, design rule specifications, previous verification run logs, and performance metrics from similar designs. This historical data may be used for training and refining an ML model, allowing the ML model to learn from past experiences and improve its predictive accuracy over time.

At block 406, the process extracts relevant input parameters 408 from the chip layout 402 and setup and log files 404. This extraction process may involve data parsing and feature engineering techniques to identify the most relevant factors for resource prediction. For example, the extraction process may analyze the chip layout to determine the number of transistors, the complexity of interconnects, and the presence of specialized structures such as memory arrays or analog components. From the setup and log files, it may extract information such as the technology node, design rules, and historical resource usage patterns for similar designs.

The extracted input parameters 408 are provided to an ML component 410. The ML component may be similar to ML component 312, described above in connection with FIG. 3. The ML component 410 may utilize various machine learning techniques such as deep neural networks, gradient boosting machines, or random forest algorithms, depending on the nature of the input data and the specific prediction tasks. In some implementations, the ML component 410 may employ transfer learning techniques, allowing it to leverage knowledge gained from predicting resources for one type of EDA task to improve its predictions for related tasks.

The ML component 410 generates predictions for RAM and CPU time 412 required for the EDA operation. In some implementations, these predictions may include temporal profiles of resource usage throughout the EDA process. For example, the ML component 410 may predict peak memory usage, CPU utilization patterns, and potential bottlenecks at different stages of the verification process.

At block 414, the process 400 includes a detailed analysis of the predicted resource requirements. This analysis may involve breaking down the predictions into specific resource types and quantities, such as the number of CPU cores, amount of RAM, storage requirements, and specialized hardware needs like GPU acceleration for certain computationally intensive tasks. The analysis may include computing both a minimum number of CPU cores required to meet baseline performance levels and a maximum number of CPU cores to handle peak loads. The analysis may also consider the temporal aspects of resource usage, identifying periods of high demand and potential opportunities for resource sharing or job scheduling optimization. Alternative embodiments of this block may incorporate machine learning algorithms to enhance the precision of resource predictions, adapting dynamically based on historical data and real-time inputs. In some implementations, an output 416 of block 414 includes a number, N, of cores (e.g., a maximum number of cores).

At block 418, the process 400 includes querying the availability of machines with a number of available cores that is greater than N and querying the availability of RAM instances for providing an amount of RAM greater that the predicted amount of RAM. At block 420, the process 400 includes determining a number of licenses required for the N cores. At block 422, the availability of the required number of licenses is queried.

At the decision block 424, if the resource estimator determines that the available number of cores is not greater than the predicted number, N, of cores and/or that the available amount of RAM is not greater than the predicted amount of RAM, R, the process 400 continues at block 426. At block 426, the resource estimator decrements N in specific quanta to reduce the license demand by 1. The process of blocks 418, 420, 422, and 424 is then repeated for N−1. This process may be iterated until N is equal to the minimum number of cores needed for the compute job or until, at the decision block 424, the resource estimator determines that the available number of cores is greater than or equal to the predicted number, N, of cores and that the available amount of RAM is greater than or equal to the predicted amount of RAM, R. In this case, the process 400 continues at block 428. At block 428, the job manager submits a compute job with a request for N cores and R RAM. Additionally, in some implementations, as shown at block 430, the job manager may display (e.g., cause a device such as device 200 shown in FIG. 2 to display) an estimated run time (e.g., predicted CPU time/N).

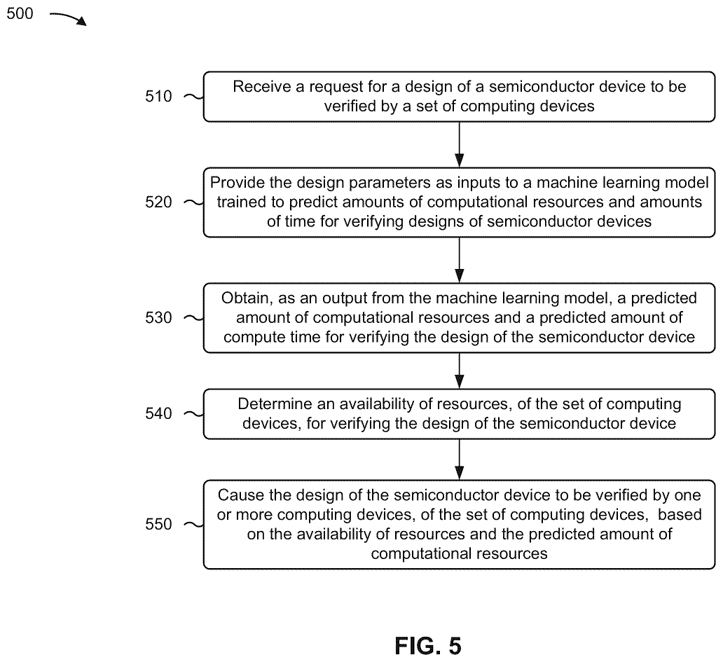

FIG. 5 is a flow diagram illustrating a process for using an ML component to predict computational hardware and software resources to be used and an amount of time to be spent for design verification of semiconductor devices, in accordance with the present disclosure.

In some implementations, one or more process blocks of FIG. 5 may be performed by a job manager (e.g., job manager 112). Additionally, or alternatively, one or more process blocks of FIG. 5 may be performed by one or more components of device 200, such as processor 220, memory 230, storage component 240, input component 250, output component 260, and/or communication interface 270.

As shown in FIG. 5, process 500 may include receiving a request for a design of a semiconductor device to be verified (block 510). For example, the job manager may receive a request for a design of a semiconductor device to be verified. The request comprises design parameters regarding the design of the semiconductor device. The design parameters identify a foundry, a technology node of the foundry, and a size of a file depicting a layout of the semiconductor device, as described above.

As shown in FIG. 5, process 500 may include providing the design parameters as inputs to a machine learning model trained to predict amounts of computational resources and amounts of time for verifying designs of semiconductor devices (block 520). For example, the job manager may provide the design parameters as inputs to a machine learning model trained to predict amounts of computational resources and amounts of time for verifying designs of semiconductor devices, wherein the machine learning model is trained using training data that includes historical design parameters for the designs, historical computational resources used for verifying the designs, and historical amounts of time for verifying the designs, as described above. In some implementations, the training data may include historical number of shapes of the designs and historical number of rules checked for the designs. In some implementations, the design parameters identify a number of shapes of the semiconductor device and a number of rules regarding the design of the semiconductor.

As shown in FIG. 5, process 500 may include obtaining, as an output from the machine learning model, a predicted amount of computational resources and a predicted amount of time for verifying the design of the semiconductor device (block 530). For example, the job manager may obtain, as an output from the machine learning model, a predicted amount of computational resources and a predicted amount of compute time for verifying the design of the semiconductor device, as described above.

As shown in FIG. 5, process 500 may include determining an availability of resources, of the set of computing devices, for verifying the design of the semiconductor device (block 540). For example, the job manager may determine an availability of resources, of the set of computing devices, for verifying the design of the semiconductor device, as described above. In some implementations, the resources may include CPUs, CPU cores, RAM, and EDA software tool licenses.

As shown in FIG. 5, process 500 may include causing the design of the semiconductor device to be verified by one or more computing devices, of the set of computing devices, based on the availability of resources and the predicted amount of computational resources (block 550). For example, the job manager may cause the design of the semiconductor device to be verified by one or more computing devices, of the set of computing devices, based on the availability of resources and the predicted amount of computational resources, as described above.

In some implementations, the process 500 may further include determining, based on the predicted amount of computational resources and the predicted amount of compute time, a quantity of cores to be used for verifying the design of the semiconductor device and a quantity of licenses to be used for verifying the design of the semiconductor device. Determining the availability of resources may include determining whether the quantity of cores and the quantity of licenses are available. In some implementations, the process 500 may include adjusting an amount of computational resources for verifying the design of the semiconductor device based on determining whether the quantity of cores and the quantity of licenses are available, wherein the amount of computational resources are reduced until a quantity threshold of cores and a quantity threshold of licenses becomes available. For example, an initial amount of computational resources may be established (e.g., assigned, allotted, indicated, and/or determined) for verifying the design of the semiconductor device. The initial amount may be established based on the predicted amount of computational resources, for example. Then, based on availability of cores and/or licenses, the initial amount of computational resources that has been established may be adjusted (e.g., reduced or increased).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code-it being understood that software and hardware can be used to implement the systems or methods based at least in part on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based at least in part on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
receiving a request for a design of a semiconductor device to be verified by a set of computing devices,
wherein the request comprises design parameters regarding the design of the semiconductor device;
providing the design parameters as inputs to a machine learning model trained to predict amounts of computational resources and amounts of compute time for verifying designs of semiconductor devices;
obtaining, as an output from the machine learning model, a predicted amount of computational resources and a predicted amount of compute time for verifying the design of the semiconductor device;
determining an availability of resources, of the set of computing devices, for verifying the design of the semiconductor device; and
causing the design of the semiconductor device to be verified by one or more computing devices, of the set of computing devices, based on the availability of resources and the predicted amount of computational resources.

2. The method of claim 1, comprising determining, based on the amount of computational resources and the predicted amount of compute time, a quantity of computer cores to be used for verifying the design of the semiconductor device and a quantity of licenses to be used for verifying the design of the semiconductor device.

3. The method of claim 2, wherein determining the availability of resources comprises determining whether the quantity of computer cores and the quantity of licenses are available.

4. The method of claim 2, comprising adjusting an amount of computational resources, of the one or more computing devices, for verifying the design of the semiconductor device based on determining whether the quantity of computer cores and the quantity of licenses are available, wherein the amount of computational resources are reduced until a quantity threshold of computer cores and a quantity threshold of licenses becomes available.

5. The method of claim 1, wherein the machine learning model is trained using training data that includes historical design parameters for the designs, historical computational resources used for verifying the designs, and historical amounts of compute time for verifying the designs, and
wherein the training data includes historical number of shapes of the designs and historical number of rules checked for the designs.

6. The method of claim 1, wherein the resources include central processor units (CPUs), CPU cores, random access memory (RAM), and electronic design automation (EDA) software tool licenses.

7. The method of claim 1, wherein the design parameters identify a foundry, a technology node of the foundry, a size of a file depicting a layout of the semiconductor device, a number of shapes of the semiconductor and a number of rules regarding the design of the semiconductor.

8. A system comprising:
one or more processing units adapted to:
receive a request for a design of a semiconductor device to be verified by a set of computing devices, wherein the request comprises design parameters regarding the design of the semiconductor device;
provide the design parameters as inputs to a machine learning model trained to predict amounts of computational resources and amounts of compute time for verifying designs of semiconductor devices;
obtain, as an output from the machine learning model, a predicted amount of computational resources and a predicted amount of compute time for verifying the design of the semiconductor device;
determine, based on the predicted amount of computational resources and the predicted amount of compute time, a quantity of cores to be used for verifying the design of the semiconductor device and a quantity of licenses to be used for verifying the design of the semiconductor device; and
cause the design of the semiconductor device to be verified by one or more computing devices, of the set of computing devices, based on the quantity of cores, the quantity of licenses, and the amount of computational resources.

9. The system of claim 8, wherein the one or more processing units are adapted to:
determine whether the quantity of licenses and the predicted amount of computational resources are available, via the set of computing devices, for verifying the design of the semiconductor device,
wherein the predicted amount of computational resources includes the quantity of cores and an amount of random access memory (RAM); and
cause the design of the semiconductor device to be verified by one or more computing devices, of the set of computing devices, based on determining whether the quantity of licenses and the predicted amount of computational resources are available.

10. The system of claim 9, wherein the one or more processing units are adapted to:
adjust an amount of computational resources, of the one or more computing devices, for verifying the design of the semiconductor device based on determining whether the quantity of cores and the quantity of licenses are available; and
provide, for display, the amount of computational resources and the predicted amount of time.

11. The system of claim 8, wherein the machine learning model is trained using:
deep learning,
supervised learning, or
unsupervised learning.

12. The system of claim 8, wherein the machine learning model includes a gradient boost model.

13. The system of claim 8, wherein the machine learning model is trained using training data that includes historical design parameters for the designs, historical computational resources used for verifying the designs, and historical amounts of compute time for verifying the designs, and
wherein the training data includes historical number of shapes of the designs and historical number of rules checked for the designs.

14. The system of claim 8, wherein the design parameters identify a foundry, a technology node of the foundry, a size of a file depicting a layout of the semiconductor device, a number of shapes of the semiconductor and a number of rules regarding the design of the semiconductor device.

15. A computer program product comprising:
one or more computer readable storage media, and program instructions collectively stored on the one or more computer readable storage media, the program instructions comprising:
program instructions to receive a request for a design of a semiconductor device to be verified by a set of computing devices,
wherein the request comprises design parameters regarding the design of the semiconductor device;
program instructions to provide the design parameters as inputs to a machine learning model trained to predict amounts of computational resources and amounts of compute time for verifying designs of semiconductor devices;
program instructions to obtain, as an output from the machine learning model, a predicted amount of computational resources and a predicted amount of compute time for verifying the design of the semiconductor device;
program instructions to determine, based on the predicted amount of computational resources and the predicted amount of compute time, a quantity of cores to be used for verifying the design of the semiconductor device and a quantity of licenses to be used for verifying the design of the semiconductor device; and
program instructions to cause the design of the semiconductor device to be verified by one or more computing devices, of the set of computing devices, based on the quantity of cores, the quantity of licenses, and the amount of computational resources.

16. The computer program product of claim 15, wherein the design parameters identify a foundry, a technology node of the foundry, a size of a file depicting a layout of the semiconductor device, a number of shapes of the semiconductor, and a number of rules regarding the design of the semiconductor device.

17. The computer program product of claim 15, wherein the machine learning model is trained using training data that includes historical design parameters for the designs, historical computational resources used for verifying the designs, and historical amounts of compute time for verifying the designs, and
wherein the training data includes historical number of shapes of the designs and historical number of rules checked for the designs.

18. The computer program product of claim 16, wherein the program instructions comprise program instructions to:
determine whether the quantity of licenses and the predicted amount of computational resources are available, via the set of computing devices, for verifying the design of the semiconductor device; and
cause the design of the semiconductor device to be verified by one or more computing devices, of the set of computing devices, based on determining whether the quantity of cores, the quantity of licenses and the predicted amount of computational resources are available.

19. The computer program product of claim 18, wherein the program instructions comprise program instructions to:
adjust an amount of computational resources for verifying the design of the semiconductor device based on determining whether the quantity of cores and the quantity of licenses are available; and
provide, for display, the amount of computational resources and the predicted amount of time.

20. The computer program product of claim 15, wherein the machine learning model trained using:
deep learning,
supervised learning, or
unsupervised learning.
